(19) United States
(12) Patent Application Publication
(10) Pub. No.: US 2026/0238173 A1
(43) Pub. Date: Aug. 13, 2026

(54) METHODS OF FABRICATING PIEZOELECTRIC ACOUSTIC LAMB WAVE RESONATORS HAVING MASS LOADING FRAMES

(71) Applicant: MACOM Technology Solutions Holdings, Inc., Lowell, MA (US)

(72) Inventors: Renyuan Wang, Windham, NH (US); Xifeng Qian, Lowell, MA (US)

(21) Appl. No.: 19/426,438

(22) Filed: Dec. 19, 2025

Related U.S. Application Data
(60) Provisional application No. 63/755,460, filed on Feb. 7, 2025.

(51) Int. Cl. H03H 3/02; H03H 3/007; H03H 9/02; H03H 9/13

(52) U.S. Cl. CPC H03H 3/02; H03H 9/02228; H03H 9/13; H03H 2003/0071

(57) ABSTRACT

A method of fabricating an acoustic wave lamb resonator comprises forming a recess in a substrate, forming a sacrificial material within the recess, forming a piezoelectric film directly on an upper surface of the substrate and on an upper surface of the sacrificial material, forming a plurality of electrodes on an upper surface of the piezoelectric film, forming an opening in the piezoelectric film, and selectively removing the sacrificial material so that the piezoelectric film is suspended above the recess.

### CROSS-REFERENCE TO RELATED APPLICATION

The present application claims priority under 35 U.S.C. § 119 to U.S. Provisional Patent Application Ser. No. 63/755,460, filed Feb. 7, 2025, the entire content of which is incorporated herein by reference as if set forth in its entirety.

### FIELD

The present application relates to filters and, more particularly, to acoustic lamb wave resonators and radio frequency (“RF”) filters formed using one or more such acoustic lamb wave resonators

### BACKGROUND

RF acoustic wave resonators are known in the art. Acoustic wave resonators convert RF energy between the mechanical domain and the electromagnetic domain through piezoelectric and inverse-piezoelectric effects. One known type of RF acoustic wave resonator is the so-called bulk acoustic wave (“BAW”) resonator, which comprises a thin piezoelectric membrane (also called a piezoelectric film) that is sandwiched between signal and ground electrodes, with the piezoelectric membrane and the electrodes suspended above a substrate. An RF electric field is applied to the piezoelectric membrane by applying an RF signal to the electrodes, which excites an alternating extension and contraction motion (i.e., an acoustic wave) in the piezoelectric film in the thickness or “depth” direction thereof through an inverse-piezoelectric effect. Another known acoustic wave resonator is the surface acoustic wave (“SAW”) resonator. In a SAW resonator, the acoustic waves travel in the piezoelectric film in a direction that is parallel to the major surfaces of the substrate instead of travelling in the depth direction through the piezoelectric film. Yet another known type of acoustic wave resonator is the RF acoustic lamb wave resonator, which is an amalgamation of BAW and SAW resonators. A plurality of acoustic wave resonators may be interconnected to provide a wide variety of different RF filters.

An acoustic lamb wave resonator comprises a piezoelectric film that is suspended above a substrate, and the acoustic wave travels laterally (i.e., parallel to the substrate) in the piezoelectric film. As such, the resonant frequencies that are generated may be defined via photolithography, as is the case with SAW filters. Moreover, since the piezoelectric film is suspended above a recess in the substrate, the acoustic wave is decoupled from the substrate and hence acoustic loss from energy radiation into the substrate may be very low. This allows RF acoustic lamb wave filters to exhibit quality factors that are similar to those provided by BAW filters. Examples of piezoelectric thin films that may be used to form RF acoustic lamb wave resonators are aluminum nitride films, scandium aluminum nitride films, LiNbO₃ (LN) and/or LiTaO₃ (LT) films.

### SUMMARY

Pursuant to embodiments of the present invention, a method of fabricating an acoustic wave lamb resonator is provided that comprises forming a recess in a substrate, forming a sacrificial material within the recess, forming a piezoelectric film directly on an upper surface of the substrate and on an upper surface of the sacrificial material, forming a plurality of electrodes on an upper surface of the piezoelectric film, forming an opening in the piezoelectric film, and selectively removing the sacrificial material so that the piezoelectric film is suspended above the recess.

In some embodiments, the substrate comprises a silicon substrate and/or the sacrificial material comprises silicon oxide.

In some embodiments, forming the recess in the substrate comprises forming a mask on an upper surface of the substrate, forming at least one opening in the mask, oxidizing the silicon in the region(s) exposed by the at least one opening in the mask to form silicon oxide region(s) within the silicon substrate, and performing an etching step to remove the silicon oxide regions. In some embodiments, forming a sacrificial material within the recess comprises performing a second oxidation process using the mask as an oxidation mask to form a sacrificial silicon oxide layer within the recess. In some embodiments, the method further comprises removing the mask and planarizing an upper surface of the silicon substrate having the sacrificial silicon oxide layer within the recess before forming the piezoelectric film.

In some embodiments, forming the recess in the substrate comprises etching the substrate to form the recess. In some embodiments, forming a sacrificial material within the recess comprises performing an oxidation process using the mask as an oxidation mask to form a sacrificial silicon oxide layer within the recess. In some embodiments, the method further comprises removing the mask and planarizing an upper surface of the silicon substrate having the sacrificial silicon oxide layer within the recess before forming the piezoelectric film.

In some embodiments, the piezoelectric film is a scandium aluminum nitride film or an aluminum nitride film. In some embodiments, the plurality of electrodes comprise a plurality of signal electrodes that are connected to a signal bus and a plurality of ground electrodes that are connected to a ground bus. In some embodiments, forming an opening in the piezoelectric film comprises using reactive ion etching to form the opening in the piezoelectric film. In some embodiments, selectively removing the sacrificial material so that the piezoelectric film is suspended above the recess comprises removing the sacrificial material via wet etching using hydrofluoric acid. In some embodiments, the mask is a silicon nitride mask.

Pursuant to further embodiments of the present invention, another method of fabricating an acoustic wave lamb resonator is provided that comprises forming a mask on a substrate, etching the substrate using the mask as an etch mask to form a recess in a substrate, forming a sacrificial material within the recess, forming a piezoelectric film directly on an upper surface of the substrate and on an upper surface of the sacrificial material, forming a plurality of electrodes on an upper surface of the piezoelectric film, forming an opening in the piezoelectric film, and selectively removing the sacrificial material so that the piezoelectric film is suspended above the recess.

In some embodiments, the mask is a photoresist pattern. In some embodiments, the substrate comprises a silicon substrate and the sacrificial material comprises silicon oxide.

In some embodiments, forming a sacrificial material within the recess comprises forming a sacrificial layer on the substrate and within the recess and planarizing an upper surface of the substrate having the sacrificial material within the recess. In some embodiments, the piezoelectric film is a scandium aluminum nitride film. In some embodiments, the plurality of electrodes comprise a plurality of signal electrodes that are connected to a signal bus and a plurality of ground electrodes that are connected to a ground bus. In some embodiments, forming an opening in the piezoelectric film comprises using reactive ion etching to form the opening in the piezoelectric film. In some embodiments, selectively removing the sacrificial material so that the piezoelectric film is suspended above the recess comprises removing the sacrificial material via wet etching using hydrofluoric acid.

In some embodiments, selectively removing the sacrificial material so that the piezoelectric film is suspended above the recess comprises delivering an etchant to the sacrificial material through an opening in the piezoelectric film.

Pursuant to additional embodiments of the present invention, yet another method of fabricating an acoustic wave lamb resonator is provided that comprises selectively oxidizing a silicon substrate to form a recess in the silicon substrate that is filled with a first silicon oxide pattern, removing the silicon oxide from the recess, selectively oxidizing the silicon substrate to fill the recess with a second silicon oxide pattern, forming a piezoelectric film directly on an upper surface of the substrate and on an upper surface of the second silicon oxide pattern, forming a plurality of electrodes on an upper surface of the piezoelectric film, forming an opening in the piezoelectric film, and selectively removing the second silicon oxide pattern so that the piezoelectric film is suspended above the recess.

In some embodiments, the method further comprises planarizing the second silicon oxide pattern prior to forming the piezoelectric film. In some embodiments, selectively oxidizing a silicon substrate to form a recess in the silicon substrate that is filled with a first silicon oxide pattern comprises forming a mask on an upper surface of the silicon substrate, forming an opening in the mask, and oxidizing the silicon in the region exposed by the opening in the mask to form the first silicon oxide pattern.

In some embodiments, the piezoelectric film is a scandium aluminum nitride film or an aluminum nitride film. In some embodiments, the plurality of electrodes comprise a plurality of signal electrodes that are connected to a signal bus and a plurality of ground electrodes that are connected to a ground bus. In some embodiments, selectively removing the sacrificial material so that the piezoelectric film is suspended above the recess comprises removing the sacrificial material via wet etching using hydrofluoric acid.

### BRIEF DESCRIPTION OF THE DRAWING

FIG. 1 is a schematic diagram that illustrates the primary steps in a process flow for fabricating a conventional RF acoustic lamb wave resonator.

FIG. 2A is a schematic top perspective view of an active region of an acoustic lamb wave resonator.

FIG. 2B is a schematic top view of a simplified version of the acoustic lamb wave resonator of FIG. 2A.

FIG. 2C is a schematic cross-sectional view taken along line 2C-2C of FIG. 2B.

FIGS. 3A-3H are schematic cross-sectional diagrams that illustrate a first approach according to embodiments of the present invention for forming a release bathtub in a substrate.

FIGS. 4A-4H are schematic cross-sectional diagrams that illustrate a second approach according to embodiments of the present invention for forming a release bathtub in a substrate.

FIGS. 5A-5F are schematic cross-sectional diagrams that illustrate a third approach according to embodiments of the present invention for forming a release bathtub in a substrate.

FIGS. 6A-6D are schematic cross-sectional diagrams that illustrate a fourth approach according to embodiments of the present invention for forming a release bathtub in a substrate.

FIGS. 7A-7E are schematic plan and cross-sectional views that illustrate subsequent processing steps that may be performed after the processing steps shown in the approaches of FIGS. 3A-3H, 4A-4H, 5A-5F and 6A-6D.

### DETAILED DESCRIPTION

While RF acoustic lamb wave resonators can readily be formed in laboratory settings, current fabrication techniques are not conducive to reliable, reproducible, volume production of such resonators. For example, RF acoustic lamb wave resonators often comprise a silicon substrate having a recess formed therein, and a piezoelectric thin film is suspended over the recess. XeF₂ is commonly used to form the recess in the silicon substrate, and a. An XeF₂ etch of silicon is an isotropic etch and the etch front is difficult to control, resulting in the recess having an irregular boundary. The irregular release boundary results in unpredictable electrical parasitic affects that cannot be accounted for a priori during the design process. Moreover, a complete RF acoustic lamb wave filter will typically comprise multiple suspended RF acoustic lamb wave resonators so that the filter may have a large overall suspended film area that is susceptible to rupture. Finally, since the XeF₂ etch is an isotropic etch, the thickness of the silicon substrate needs to be thick enough to prevent substrate punch-through during the etching process. The provision of such thick substrates may be incompatible with customer demands for low profile components.

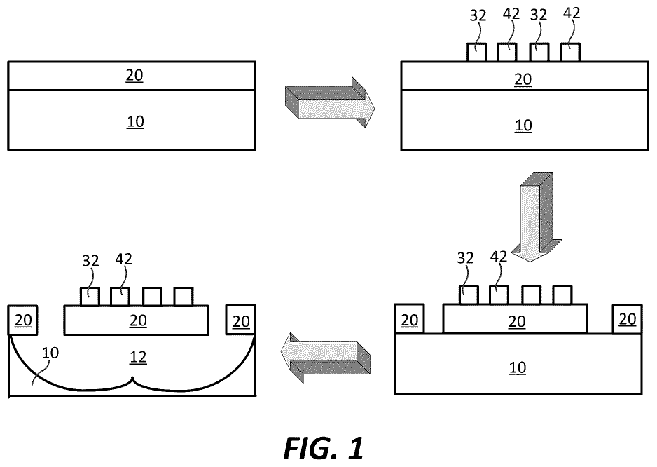

FIG. 1 is a schematic diagram that illustrates the primary steps in a process flow for fabricating a conventional RF acoustic lamb wave resonator. As shown in FIG. 1, a substrate 10 is provided, and a piezoelectric film 20 is formed on the upper surface of the substrate 10 by, for example, magnetron reactive sputtering. Metal, finger-shaped, signal and ground electrodes 32, 42 are subsequently deposited on the piezoelectric film 20 by either evaporation or sputtering depending on the choice of electrode material and method of pattern definition (e.g., lift-off, etching). The piezoelectric film 20 is then patterned by, for example, reactive ion etching. Thereafter, the piezoelectric film 20 is “released” by a selective XeF₂ etch of the substrate 10 in the region underneath the piezoelectric film 20. As discussed previously, the etching step is an isotropic etch and the device geometry interferes with the etch front leading to large release regions (recesses) 12 that have unpredictable boundaries. This may lead to significant production yield issues due to cracking of the piezoelectric films 20 and unpredictable parasitic affects from the transition between the released region 12 and the solid-mounted regions of the piezoelectric film 20.

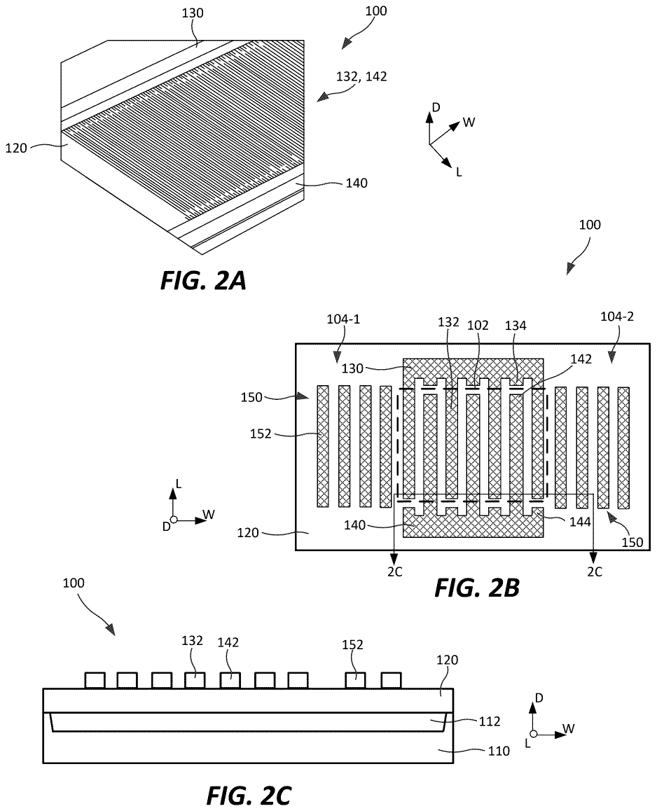

FIGS. 2A-2C schematically illustrate an acoustic lamb wave resonator 100 that may be fabricated using the techniques according to embodiments of the present invention that are discussed below. In particular, FIG. 2A is a schematic top perspective view of a portion of an active region of the acoustic lamb wave resonator 100. FIG. 2B is a schematic top view of a simplified version of the acoustic lamb wave resonator 100 that illustrates how the active region is bordered on opposed sides by inactive regions that include grating reflectors. Finally, FIG. 2C is a schematic cross-sectional view taken along line 2C-2C of FIG. 2B. It should be noted that in the schematic views of FIGS. 2B and 2C, only a few of the electrode pairs that are formed in the active region are shown to simplify these figures. Typically, there will be a much larger number of electrodes, as is shown in FIG. 2A.

As shown in FIGS. 2A-2C, the acoustic lamb wave resonator 100 includes a substrate 110 that has an air-filled recess 112 formed in an upper surface thereof. The substrate 110 may comprise a silicon substrate. A thin piezoelectric film 120 such as a scandium aluminum nitride film is provided above the recess 112. The thin piezoelectric film 120 also extends onto the upper surface of the substrate 110. A metal signal bus 130 and a metal ground bus 140 are formed on an upper surface of the thin piezoelectric film 120. A plurality of signal electrodes 132 extend from the signal bus 130 toward the ground bus 140, and a plurality of ground electrodes 142 extend from the ground bus 140 toward the signal bus 130. The signal bus 130 and the ground bus 140 may extend in parallel to each other with their respective longitudinal axes extending in a “width” direction W of the acoustic lamb wave resonator 100. The signal electrodes 132 and the ground electrodes 142 may extend in parallel to each other with their respective longitudinal axes extending in a “length” direction L of the acoustic lamb wave resonator 100, where the length direction L is perpendicular to the width direction W. A depth direction D of the acoustic lamb wave resonator 100 extends perpendicularly to the width and length directions W, L (and hence perpendicular to the major surfaces of the thin piezoelectric film 120. It should be noted that the extent of an acoustic lamb wave resonator may be greater in the width direction W that in the length direction L.

The signal and ground electrodes 132, 142 may be much longer in the length direction than in the width direction (e.g., the length of each signal and ground electrode 132, 142 may be twenty to two hundred times its width in example embodiments). The signal bus 130 may further include a plurality of signal stubs 134 that extend a short distance toward the ground bus 140. Each signal stub 134 may be aligned in the length direction L with a respective one of the ground electrodes 142. Similarly, the ground bus 140 may further include a plurality of ground stubs 144 that extend a short distance toward the signal bus 130. Each ground stub 144 may be aligned in the length direction L with a respective one of the signal electrodes 132.

The signal bus, 130, the ground bus 140, and the outer ones of the signal/ground electrodes 132, 142 define an active region 102 of the acoustic lamb wave resonator 100. The active region 102 is shown by the dashed box in FIG. 2B. Inactive regions 104-1 and 104-2 are provided on opposed sides of the active region 102. A plurality of electrically floating metal electrodes 152 are provided in each inactive region 104. Each electrically floating electrode 152 has a longitudinal axis that extends in the length direction L, and lengths of the floating electrodes 152 may be the same as or similar to the lengths of signal electrodes 132 and the ground electrodes 142. The floating metal electrodes 152 may have the same pitch as the signal/ground electrodes 132/142 in the active region 102, and form an acoustic grating reflector 150 in each inactive region 104-1, 104-2. The acoustic grating reflectors 150 enhance confinement of acoustic energy within the active region 102.

The signal electrodes 132 and the ground electrodes 142 are spaced apart from one another in the width direction in alternating fashion so that (except at the opposed side edges of the active region 102) a ground electrode 142 is provided on either side of each signal electrode 132, and a signal electrode 132 is provided on either side of each ground electrode 142. In other words, the signal electrodes 132 and the ground electrodes 142 are disposed in alternating fashion on the piezoelectric film 120.

During device operation, the signal and ground electrodes 132, 142 are excited by an RF signal to establish electric fields in the piezoelectric film 120 with alternating directions, which acts to excite lamb waves that travel in the piezoelectric film 120 in the lateral direction (i.e., parallel to the major surfaces of the piezoelectric film 120). The signal and ground electrodes 132, 142 also periodically disturb the mechanical boundary condition leading to periodical reflections which, in essence, forms an acoustic grating reflector. If required, energy confinement can be enhanced by providing the above-discussed electrically inactive or “floating” electrodes 152 on opposed sides of the active region 102. The acoustic lamb wave resonator 100 will be resonant at the frequency, where the acoustic wavelength is twice of pitch of the signal/ground electrodes 132, 142, and the structure can be viewed as multiple lateral half wavelength cavities connected in series in the direction perpendicular to the length direction L.

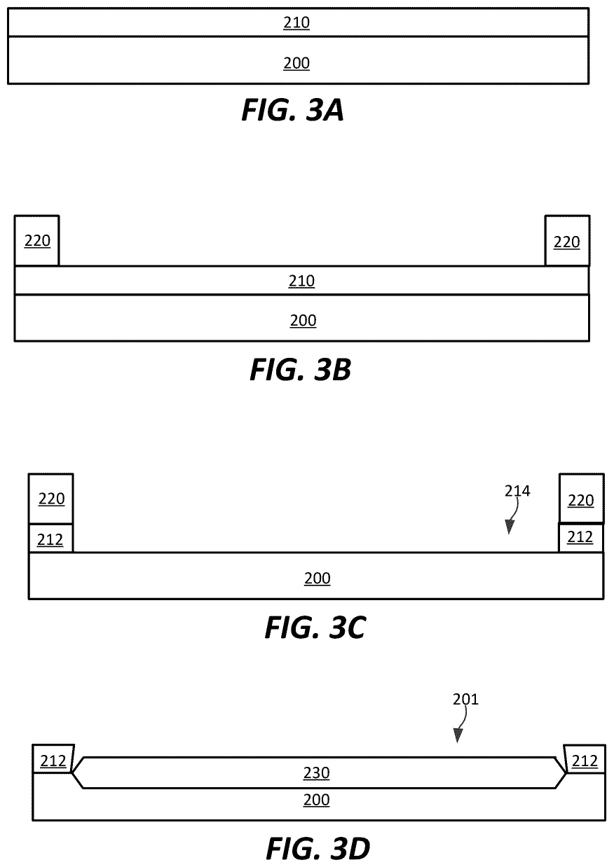

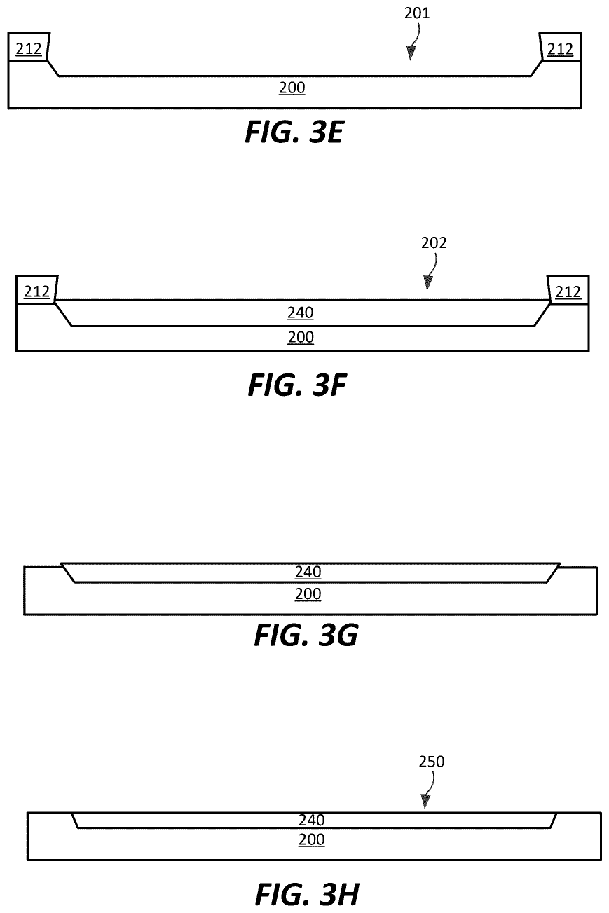

Pursuant to embodiments of the present invention, methods of manufacturing acoustic lamb wave resonators are provided that may be suitable for high volume manufacturing. In various embodiments, a recess (also commonly referred to as a release region or release bathtub) is formed in a substrate prior to formation of a thin piezoelectric film. The release bathtub may be filled with a sacrificial material such as, for example, silicon oxide, a spin-on phosphate glass or the like. The sacrificial material allows formation of the piezoelectric film (as the piezoelectric film may be formed on the sacrificial material) and the sacrificial material may thereafter be removed to form a recess under a portion of the piezoelectric film. The release bathtub structure may be conceptually similar to the release bathtubs provided in some conventional BAW resonators. The release bathtub structure can be formed using a variety of different approaches that are described below with reference to FIGS. 3A-7E. It should be noted that, for simplicity, these figures only show the formation of a single release bathtub. As discussed above, in most commercial devices, a plurality of acoustic lamb wave resonators are formed on a single substrate and electrically interconnected to form an acoustic lamb wave filter having desired filtering properties.

FIGS. 3A-3G illustrate a first approach for forming a so-called release bathtub 250 in a substrate 200 such as a silicon substrate. The release bathtub 250 refers to a recess in the substrate 200 that is filled with a sacrificial material that is removed in a subsequent process after a piezoelectric film is formed over the release bathtub 250.

As shown in FIG. 3A, a mask layer 210 such as a silicon nitride mask layer is formed on a high resistivity substrate 200 such as, for example, a high resistivity silicon wafer. The high resistivity of the substrate 200 helps reduce RF losses in the completed device. The mask layer 210 may be formed by, for example, chemical vapor deposition. Referring to FIG. 3B, a photoresist layer is formed on the mask layer 210 and patterned to provide a photoresist pattern 220. As shown in FIG. 3C, the mask layer 210 is then patterned using the photoresist pattern 220 as a mask so that one or more openings 214 are formed in the mask layer 210 in regions that will correspond to one or more release bathtubs 250, thereby converting the mask layer 210 into a patterned mask 212.

Referring to FIG. 3D, a thermal oxidation process is then performed to oxidize the silicon in the upper surface of the silicon substrate 200 that is exposed by the opening 214 in the patterned mask 212. The parameters of the thermal oxidation process may be controlled to oxidize the exposed silicon to form a first silicon oxide layer 230 that has a predetermined thickness. As shown, the oxidation process converts a portion of the upper surface of the silicon substrate 200 into silicon oxide and also results in the silicon oxide “growing” above a plane defined by the upper surface of the silicon substrate 200 prior to the thermal oxidation process. Thus, the structure shown in FIG. 3D may be viewed as a silicon substrate 200 that has a first recess 201 formed therein that is filled with a first silicon oxide layer 230. The first silicon oxide layer 230 grows above the plane defined by the upper surface of the silicon substrate 200 prior to the thermal oxidation step. The photoresist pattern 220 is then removed. As shown in FIG. 3E, an etching process (e.g., a wet etching process) is then performed to remove the silicon oxide layer 230 (with the patterned mask 212 serving as an etch mask) so that the first recess 201 may be substantially devoid of silicon oxide. As shown in FIG. 3F the exposed silicon of the silicon substrate 200 is then oxidized again via a second (e.g., thermal) oxidation process to form a second silicon oxide layer 240. The second thermal oxidation process converts additional portions of the silicon substrate 200 into silicon oxide so that the first recess 201 is converted into a second recess 202 that may extend deeper into the silicon substrate 200 than the first recess 201. As shown in FIG. 3F, the second silicon oxide layer 240 may fill the second recess 202. An upper surface of the second silicon oxide layer 240 may be close to being coplanar with an upper surface of the silicon substrate 200 that is covered by the patterned mask 212, although the second silicon oxide layer 240 may optionally extend above the second recess 202, as shown. As shown in FIG. 3G, the patterned mask 212 may then be removed. Finally, as shown in FIG. 3H, an optional polishing step may be performed to further planarize the upper surface of the silicon substrate 200 and the upper surface of the second silicon oxide layer 240. The region of the silicon substrate 200 in which the silicon has been replaced with the planarized second silicon oxide layer 240 may be viewed as a second recess 202 in the silicon substrate 200 that is filled with the second silicon oxide layer 240. The second recess 202 acts as the release bathtub 250. The above-described process provides a planar surface for subsequent deposition of a piezoelectric film on the release bathtub 250.

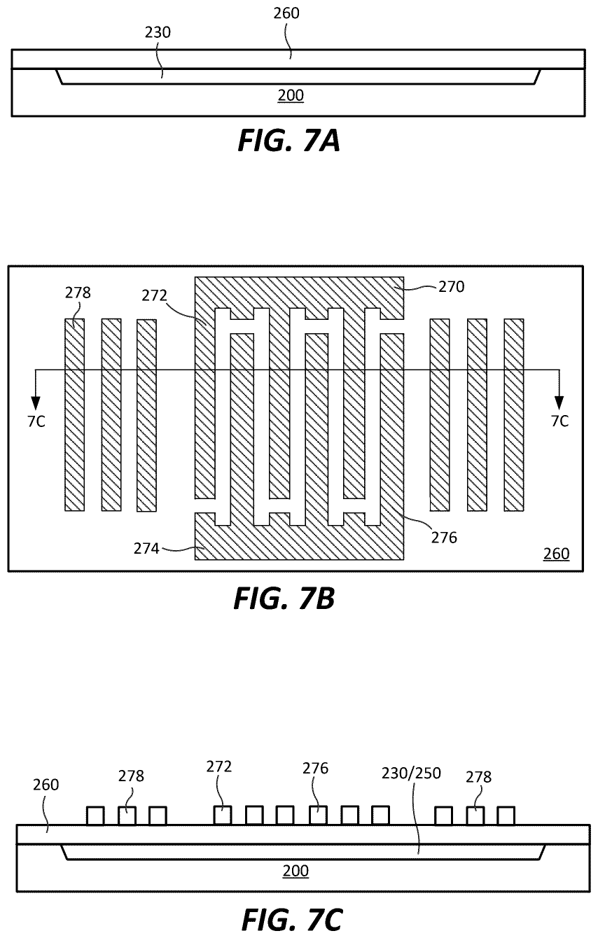

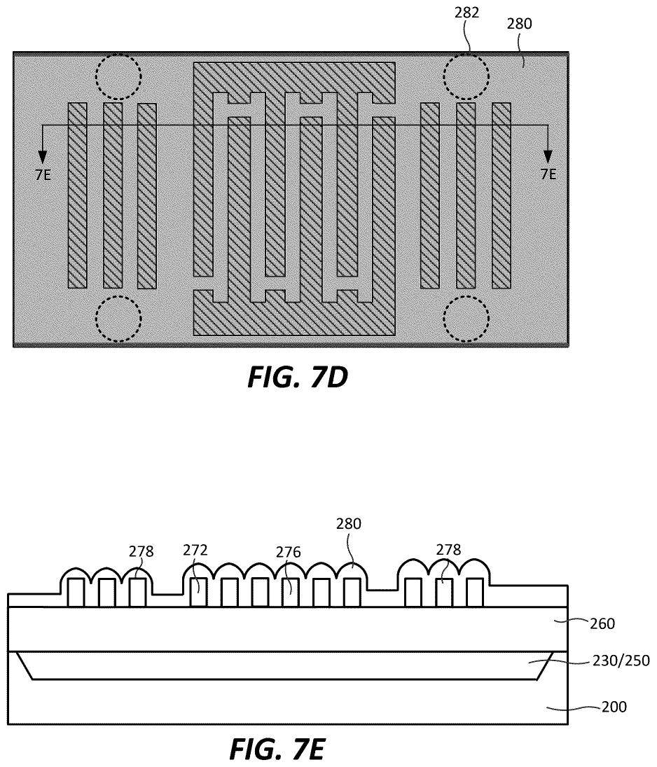

As shown in FIGS. 3A-3H, pursuant to some embodiments of the present invention, a method of manufacturing an acoustic lamb wave resonator is provided in which a recess 202 is formed in a substrate 200. A sacrificial material 240 is within the recess 202. As will be discussed below with reference to FIGS. 7A-7E, a piezoelectric film 260 is formed directly on an upper surface of the substrate 200 and on an upper surface of the sacrificial material 240, and a plurality of electrodes 272, 276 are formed on an upper surface of the piezoelectric film 260. Thereafter, an opening 282 may be formed in the piezoelectric film 260, and the sacrificial material 240 may be selectively removed so that the piezoelectric film 260 is suspended above the recess 202.

As is also shown in FIGS. 3A-3H, pursuant to embodiments of the present invention, a method of manufacturing an acoustic lamb wave resonator is provided in which a silicon substrate 200 is selectively oxidized to form a first recess 201 therein that is filled with a first silicon oxide pattern 230. The first silicon oxide pattern 230 may then be partially of fully removed from the first recess 201. The silicon substrate 200 may then be selectively oxidized to fill the first recess 201 with a second silicon oxide pattern 240 and to convert an additional region of the silicon substrate 200 into silicon oxide, thereby converting the first recess 201 into a second recess 202. As will be discussed below with reference to FIGS. 7A-7E below, thereafter a piezoelectric film 260 may be formed directly on an upper surface of the substrate 200 and on an upper surface of the second silicon oxide pattern 240, and a plurality of electrodes 272, 276 may be formed on an upper surface of the piezoelectric film 260. Later, an opening 282 may be formed in the piezoelectric film 260, and the second silicon oxide pattern 240 may be selectively removed so that the piezoelectric film 260 is suspended above the second recess 202.

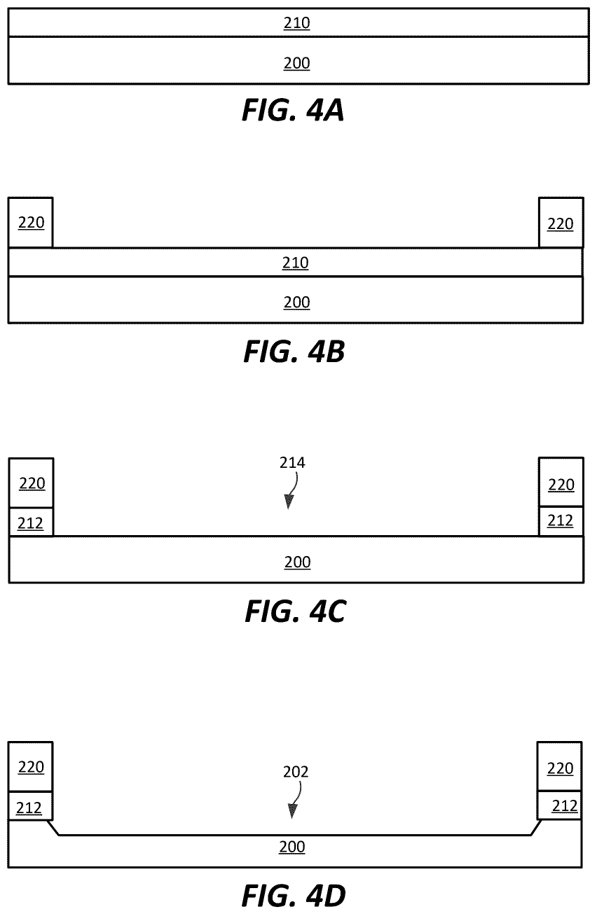

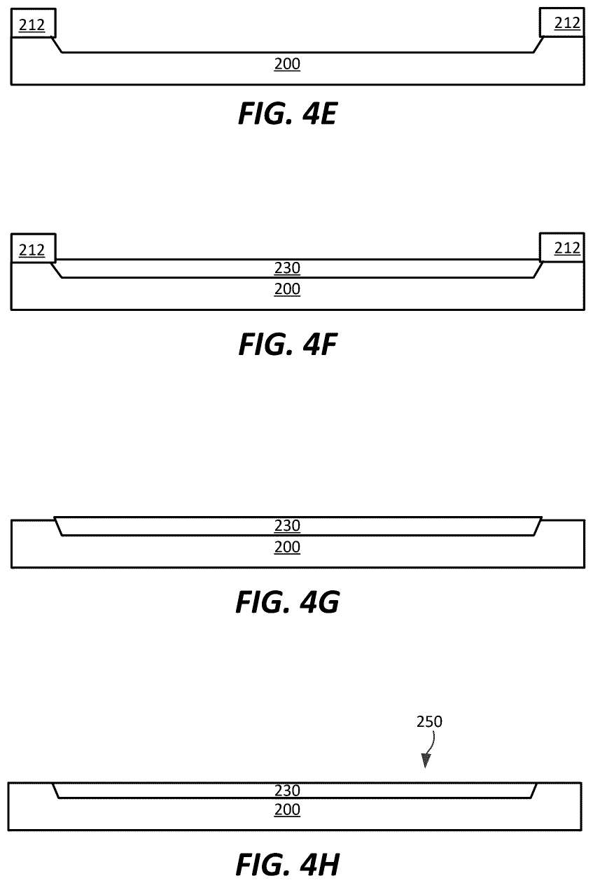

Referring to FIGS. 4A-4H, a second process according to embodiments of the present invention for forming the release bathtub 250 is illustrated. This process is similar to the process described above with reference to FIGS. 3A-3H, but only includes a single thermal oxidation step. The processing steps shown in FIGS. 4A-4C are the same steps shown in FIGS. 3A-3C above, and hence further description of these steps will be omitted. As shown in FIG. 4D, next, the substrate 200 is etched using a reactive ion etch or a wet etch to form a recess 202 therein. Then, the photoresist pattern 220 is removed, as shown in FIG. 4E. The processing steps shown in FIGS. 4F-4H are almost identical to the processing same steps shown in FIGS. 3F-3H above, with the one difference being that in FIGS. 4F-4H it is a first silicon oxide layer 230 that is formed to fill the recess 212, and thereafter polished and planarized, wherein in FIGS. 3F-3H these actions are performed with respect to a second silicon oxide layer. As such, further description of these steps will be omitted.

As shown in FIGS. 4A-4H, pursuant to further embodiments of the present invention, a method of manufacturing an acoustic lamb wave resonator is provided in which a a mask 212 is formed on a substrate 200. The substrate 200 is etched using the mask 212 as an etch mask to form a recess 202 in the substrate 200. A sacrificial material 230 is then formed within the recess 202. As will be discussed below with reference to FIGS. 7A-7E below, thereafter a piezoelectric film 260 may be formed directly on an upper surface of the substrate 200 and on an upper surface of the sacrificial material 230, and a plurality of electrodes 272, 276 may be formed on an upper surface of the piezoelectric film 260. Later, an opening 282 may be formed in the piezoelectric film 260, and the sacrificial material 230 may be selectively removed so that the piezoelectric film 260 is suspended above the recess 202.

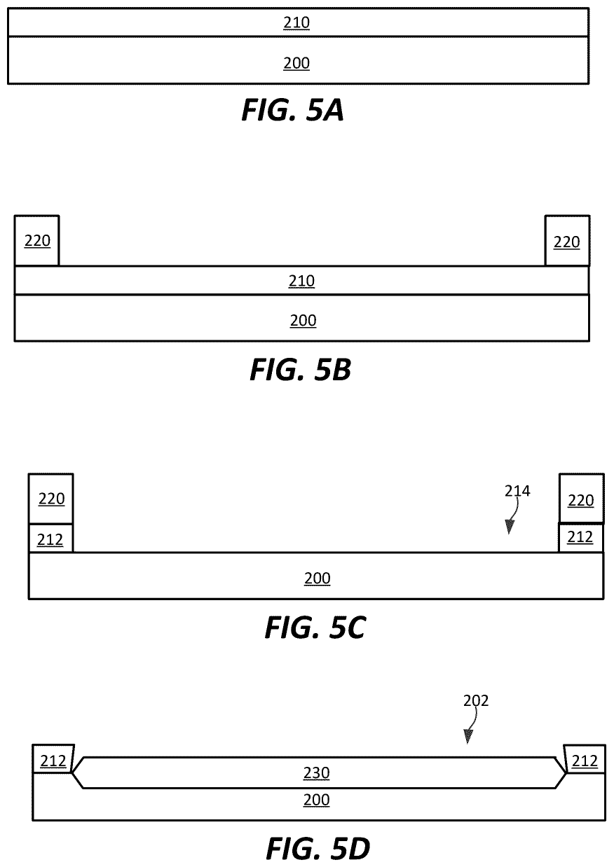

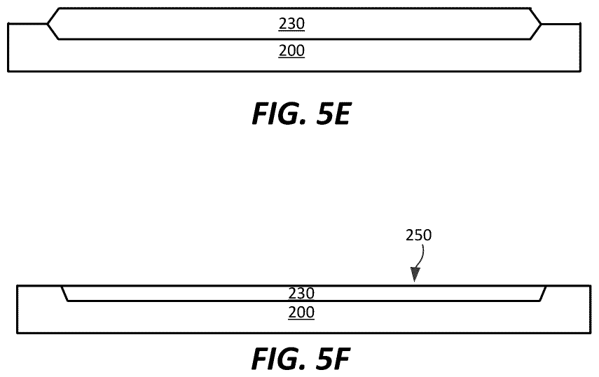

Referring to FIGS. 5A-5F, a third process according to embodiments of the present invention for forming the release bathtub 250 is illustrated. This process is similar to the process described above with reference to FIGS. 3A-3H, but again only includes a single thermal oxidation step. The processing steps shown in FIGS. 5A-5D are the same steps shown in FIGS. 3A-3D above, and hence further description of these steps will be omitted. As shown in FIG. 5E, next, the patterned mask 212 may be removed. As shown in FIG. 5F, a polishing step (e.g., a chemical mechanical polishing process) may then be performed to planarize the upper surface of the structure.

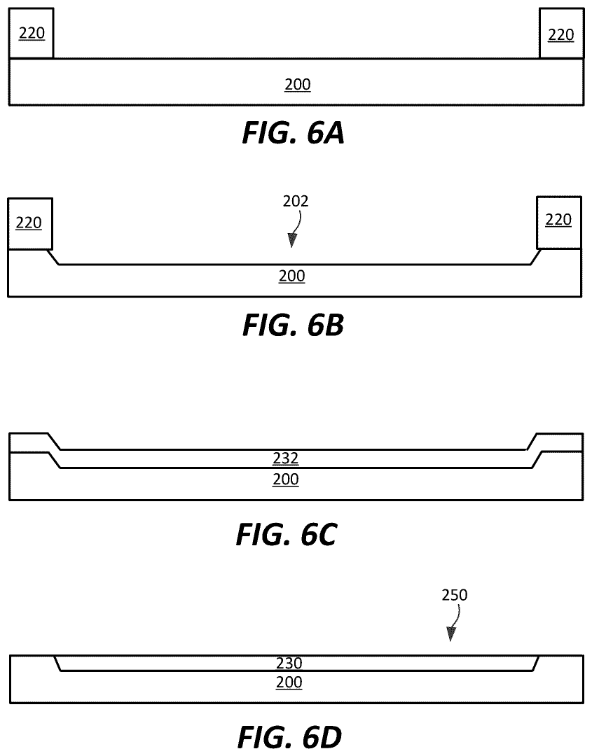

Referring to FIGS. 6A-6D, a fourth process according to embodiments of the present invention for forming the release bathtub 250 is illustrated. As shown in FIG. 6A, a photoresist layer may be formed on a substrate 200 and then patterned to provide a photoresist pattern 220. As shown in FIG. 6B, a portion of the substrate 200 that is exposed through the photoresist pattern 220 is then etched using, for example, a reactive ion etch and/or a wet etching process in order to form a recess 202 in the substrate 200. The photoresist pattern 220 may then be removed (see FIG. 6C). Next, as shown in FIG. 6C, a sacrificial layer 232 such as a PECVD oxide layer or a spin-on phosphate glass layer is blanket deposited on the substrate 200 so as to fill the recess 202. Then, as shown in FIG. 6D, a polishing operation is performed to remove portions of the sacrificial material that protrude above an upper surface of the substrate 200 so as to provide a release bathtub 250 in the substrate 200.

FIGS. 7A-7E illustrate processing steps that may be performed after the release bathtub 250 is formed using, for example, one of the four techniques discussed above with reference to FIGS. 3A-6D. As shown in FIG. 7A, a piezoelectric film 260 such as, for example, an aluminum nitride film or a scandium aluminum nitride film, is blanket-deposited via, for example, sputtering, on the upper surface of the substrate 200 with a release bathtub 250 that is filled with a sacrificial material formed therein. As shown in FIGS. 7B-7C, a signal bus 270, signal electrodes 272, a ground bus 274, ground electrodes 276 and floating electrodes 278 may then be formed on the piezoelectric film 260 by a lift-off process. While FIGS. 7A-7C illustrate a single acoustic lamb wave resonator on the substrate 200, as discussed above, typically a plurality of acoustic lamb wave resonators are formed on the substrate 200 (above the release bathtub) and are electrically interconnected to form an acoustic lamb wave filter having desired properties (e.g., roll-off, etc.). While not shown in the figures, an additional metal deposition step may be performed after the metal deposition step discussed in FIG. 7B that deposits metal that is used to interconnect the multiple acoustic lamb wave resonators in a desired fashion. A separate metal deposition step may be used (as opposed to forming these interconnections as part of the metal deposition step discussed above with respect to FIGS. 7B-7C) because it may be desired to use metal structures that are thicker than the signal and ground electrodes 272, 276 so that the interconnecting metal structures will have reduced resistance. It will be appreciated, however, that the interconnecting metal structures may alternatively be formed as part of the metal deposition step discussed above with respect to FIGS. 7B-7C.

As shown in FIGS. 7D-7E, thereafter, a silicon nitride passivation 280 may be blanket deposited on the upper surface of the device and the silicon nitride passivation 280 may then be etched to form openings therein for metal pads, transmission lines and the like, and a metal deposition step may be performed to form such metal structures in the openings in the silicon nitride passivation. Finally, an etching step (or other material removal process such as, for example, argon ion milling) may be performed to form chemical release windows 282. The chemical release windows are shown schematically as dashed circles in FIG. 7D. Example etching processes that may be used include reactive ion etching and wet chemical etching. Thereafter, the device may be “released” in diluted hydrofluoric acid, buffered hydrofluoric acid or other suitable etchants so as to remove the sacrificial material in the release bathtub 250. As diluted hydrofluoric acid does not etch silicon or the metal structures, it acts to selectively remove the silicon oxide in the release bathtub(s) 250, thereby providing a suspended thin film device. This allows precision control over the release region boundary, depth and size with reproducible parasitic affects, and also reduces the area of the suspended piezoelectric membrane, resulting in a more robust piezoelectric membrane that is resistant to rupturing.

The above-described techniques provide a commercially practical fabrication process for RF acoustic wave lamb resonators that include, for example, aluminum nitride or scandium aluminum nitride piezoelectric films. Pursuant to these techniques, a release bathtub having a predetermined shape and size that is filled with a sacrificial material is formed in a substrate prior to formation of the piezoelectric film. The sacrificial material is then removed in a later processing step. The techniques disclosed herein enable accurate control of the boundary of the suspended thin piezoelectric film mitigating thin-film rupture issues, and parasitic affects associated with the transition from the suspended thin-film to the solid-mounted thin-film.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10% unless otherwise indicated.

As used herein, two elements of an acoustic wave resonator are considered to “vertically overlap” if an axis that is perpendicular to the major surfaces of a substrate of the acoustic wave resonator intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes,” “including” and “having” when used herein, specify the presence of stated features, elements, and/or components, but do not preclude the presence or addition of one or more other features, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical embodiments of the invention and, although specific terms are employed, they are used in a generic and descriptive sense only and not for purposes of limitation, the scope of the invention being set forth in the following claims.

1. A method of fabricating an acoustic wave lamb resonator, the method comprising:
forming a recess in a substrate;
forming a sacrificial material within the recess;
forming a piezoelectric film directly on an upper surface of the substrate and on an upper surface of the sacrificial material;
forming a plurality of electrodes on an upper surface of the piezoelectric film;
forming an opening in the piezoelectric film; and
selectively removing the sacrificial material so that the piezoelectric film is suspended above the recess.

2. The method of claim 1, wherein the substrate comprises a silicon substrate and the sacrificial material comprises silicon oxide.

3. The method of claim 2, wherein forming the recess in the substrate comprises:
forming a mask on an upper surface of the substrate;
forming at least one opening in the mask;
oxidizing the silicon in the region(s) exposed by the at least one opening in the mask to form silicon oxide region(s) within the silicon substrate; and
performing an etching step to remove the silicon oxide regions.

4. The method of claim 3, wherein forming a sacrificial material within the recess comprises performing a second oxidation process using the mask as an oxidation mask to form a sacrificial silicon oxide layer within the recess.

5. The method of claim 4, further comprising:
removing the mask; and
planarizing an upper surface of the silicon substrate having the sacrificial silicon oxide layer within the recess before forming the piezoelectric film.

6. (canceled)

7. The method of claim 1, wherein forming the recess in the substrate comprises etching the substrate to form the recess, and wherein forming a sacrificial material within the recess comprises performing an oxidation process using the mask as an oxidation mask to form a sacrificial silicon oxide layer within the recess.

8. The method of claim 7, further comprising:
removing the mask; and
planarizing an upper surface of the silicon substrate having the sacrificial silicon oxide layer within the recess before forming the piezoelectric film.

9-11. (canceled)

12. The method of claim 1, wherein selectively removing the sacrificial material so that the piezoelectric film is suspended above the recess comprises removing the sacrificial material via wet etching using hydrofluoric acid.

13. (canceled)

14. A method of fabricating an acoustic wave lamb resonator, the method comprising:
forming a mask on a substrate;
etching the substrate using the mask as an etch mask to form a recess in the substrate;
forming a sacrificial material within the recess;
forming a piezoelectric film directly on an upper surface of the substrate and on an upper surface of the sacrificial material;
forming a plurality of electrodes on an upper surface of the piezoelectric film;
forming an opening in the piezoelectric film; and
selectively removing the sacrificial material so that the piezoelectric film is suspended above the recess.

15. The method of claim 14, wherein the mask is a photoresist pattern.

16. (canceled)

17. The method of claim 14, wherein forming a sacrificial material within the recess comprises:
forming a sacrificial layer on the substrate and within the recess; and
planarizing an upper surface of the substrate having the sacrificial material within the recess.

18. The method of claim 17, wherein the piezoelectric film is a scandium aluminum nitride film.

19. The method of claim 18, wherein the plurality of electrodes comprise a plurality of signal electrodes that are connected to a signal bus and a plurality of ground electrodes that are connected to a ground bus.

20. The method of claim 19, wherein forming an opening in the piezoelectric film comprises using reactive ion etching to form the opening in the piezoelectric film.

21. (canceled)

22. The method of claim 14, wherein selectively removing the sacrificial material so that the piezoelectric film is suspended above the recess comprises delivering an etchant to the sacrificial material through an opening in the piezoelectric film.

23. A method of fabricating an acoustic wave lamb resonator, the method comprising:
selectively oxidizing a silicon substrate to form a recess in the silicon substrate that is filled with a first silicon oxide pattern;
removing the silicon oxide from the recess;
selectively oxidizing the silicon substrate to fill the recess with a second silicon oxide pattern;
forming a piezoelectric film directly on an upper surface of the substrate and on an upper surface of the second silicon oxide pattern;
forming a plurality of electrodes on an upper surface of the piezoelectric film;
forming an opening in the piezoelectric film; and
selectively removing the second silicon oxide pattern so that the piezoelectric film is suspended above the recess.

24. The method of claim 23, further comprising planarizing the second silicon oxide pattern prior to forming the piezoelectric film.

25. The method of claim 24, wherein selectively oxidizing a silicon substrate to form a recess in the silicon substrate that is filled with a first silicon oxide pattern comprises:
forming a mask on an upper surface of the silicon substrate;
forming an opening in the mask;
oxidizing the silicon in the region exposed by the opening in the mask to form the first silicon oxide pattern.

26. (canceled)

27. The method of claim 25, wherein the plurality of electrodes comprise a plurality of signal electrodes that are connected to a signal bus and a plurality of ground electrodes that are connected to a ground bus.

28. The method of claim 27, wherein selectively removing the sacrificial material so that the piezoelectric film is suspended above the recess comprises removing the sacrificial material via wet etching using hydrofluoric acid.
